(19) United States
(12) Patent Application Publication
(10) Pub. No.: US 2008/0192794 A1
(43) Pub. Date: Aug. 14, 2008

(54) Lateral-Bragg-Grating-Surface-Emitting Laser/Amplifier (LBGSE)

(76) Inventor: Jacob Meyer Hammer, (US)

Correspondence Address: Jacob M. Hammer, 42 City Gate Ln, Annapolis, MD, 21401, US

(21) Appl. No.: 11/846,620

(22) Filed: Aug. 29, 2007

Related U.S. Application Data
(60) Provisional application No. 60/901,243, filed on Feb. 14, 2007.

(51) Int. Cl. H01S 5/12; H01S 5/125

(52) U.S. Cl. 372/96; 372/102

(57) ABSTRACT

A traveling-wave, surface-emitting-optical-waveguide amplifier uses Bragg gratings to provide both confinement in the lateral direction and couple light out of the waveguide plane. The grating lines are parallel to the direction of flow of the optical mode in the traveling-wave amplifier and result in emission along the entire length of the amplifier. The parallel grating does not cause feedback into the optical mode so that laser oscillation in the traveling wave amplifier is avoided. At the same time the continuous output coupling provided by the grating avoids the deleterious effect of power saturation. In this way coherent light is emitted from a very wide and long area resulting in very high power and outstanding low beam divergence.

A DFB or DBR laser may be included monolithically as the power source for the amplifier and to obtain a Master-oscillator-power amplifier (MOPA) with outstanding performance.

### CROSS-REFERENCE TO RELATED APPLICATIONS

This Non-Provisional patent application claims priority over the provisional application Ser. No. 60/901,243, entitled LATERAL-BRAGG-GRATING-SURFACE-EMITTING LASER/AMPLIFIER (LBGSE) filed Feb. 14, 2007, and named Jacob Meyer Hammer as inventor, which is hereby incorporated by reference for all purposes.

### TECHNICAL FIELD OF THE INVENTION

This invention relates to semiconductor lasers and amplifiers, and more specifically to surface emitting semiconductor lasers and amplifiers.

### CLASS 372,

### COHERENT LIGHT GENERATORS

### CLASS 385,

### OPTICAL WAVEGUIDES

subclasses 333+ for laser used as amplifiers

### REFERENCES CITED

### U.S. Patent Documents

| | | |
|---|---|---|
| 5,970,081 | October 1999 | Hirayama et.al |
| 6,963,597 | November 2005 | Evans et.al |

### OTHER PUBLICATIONS

[1] Observation of confined propagation in Bragg waveguides,” A. Y. Cho, A Yariv, P Yeh, Appl. Phys. Lett., Vol. 30, pp 461-472, 1 May 1977
[2] “Coupled-wave formalism for optical waveguiding by transverse Bragg reflection,” A. Yariv, Optics Lett. Vol. 27, pp 936-938, 1 Jun. 2002
[3] “Loss optimization by transverse Bragg resonance waveguides,” J. M. Choi, W. Liang, Y. Xu, A. Yariv, J. Opt. Soc. Am. A, Vol. 21, pp 426-429, March 2004
[4] “Transverse Bragg resonance enhancement of modulation and switching” W. Liang, Y. Xu, J. M. Choi, A. Yariv, W. Ng, Photon. Tech. Lett. Vol. 16, pp 2236-2239, October 2004.

[5] “Surface emitting semiconductor lasers and array” G. A. Evans and J. M. Hammer Eds., Academic Press, Boston, p. 124, 1993
[6] “Quantum cascade lasers with lateral double-sided distributed feedback grating” S. Golka, C. Pflügl, W. Schrenk, and G. Strasser Appl. Phys. Lett. Vol. 86, 111103 (2005)
[7] “High performance InP-based quantum cascade distributed feedback lasers with deeply etched lateral gratings,” K. Kennedy, A. B. Krysa, J. S. Roberts, K. M. Groom, and R. A. Hogg D. G. Revin, L. R. Wilson, and J. W. Cockburn, Appl. Phys. Lett. Vol. 89, 201117(2006)

### BACKGROUND

There is need for high-power sources of coherent light for fiber and free space optical communication and for applications in lithography and material processing. Grating surface emitting lasers have been a source for such uses. Existing grating surface emitters are restricted in emission area because the lateral confinement is provided by structures which act as refractive index guides and use gratings with lines that have components at right angles to the light flow in the amplifier. Thus, attempting to increase the emission area by lengthening the amplifier or extending the gratings in the lateral direction as in Refs [6] and [7] causes increased feedback which results in undesired oscillations and instabilities in the amplifier. In the lateral-Bragg grating approach of this invention the gratings do not cause feedback into the amplifier mode and light is coupled out of the amplified-traveling wave all along the amplifier length. The strength of the gratings, which provide lateral guidance as well as emission, can be adjusted to allow for a wide lateral dimension. Thus, the light intensity in the amplifier is held at a constant value and both the length and width of the emitting area can be made very large. This approach avoids both feedback and saturation effects, and thus allows for the emission of a coherent light beam with very high power from a large emitting area. The beam from such an emitter allows high collimation and can result in extraordinary power density in a large focused spot.

### SUMMARY AND INTRODUCTION

An embodiment of the Lateral-Bragg Grating-Surface-Emitting Laser/Amplifier, which I will refer to as the LBGSE, is illustrated in FIGS. 1,2 and 3. FIG. 1 is a schematic perspective sketch. FIG. 2 is a schematic cross section parallel to the x-y plane through a laterally-symmetric embodiment of the LBGSE. FIG. 3 is a schematic cross section parallel to the x-y plane through a laterally-asymmetric embodiment of the LBGSE. Coherent-guided light traveling in the z direction is amplified along the length of the traveling-wave amplifier by the active layers 50 and simultaneously radiated out of the Bragg grating wings 10.

The structures illustrated act as waveguides to partially confine the light in the y and x directions. Confinement in the x or transverse direction is provided by layers 30, 40, 50, 60 parallel to the y-z plane. Confinement in the y or lateral direction is provided by the second order of the lateral Bragg grating 10. The first order of the lateral Bragg grating 10 couples light out (out-coupling) of the y-z plane at an angles Θ from the normal (x) to the planes of the transverse waveguide.

The layers that form the ridge and the layer regions beneath the ridge are called the “ridge region.” Traveling-wave gain is obtained by applying voltage between the ridge contact 20 and the substrate contact 70 as is known in the art. In the preferred embodiment the active layers 50 consist of multi-quantum wells, MQWs. The applied voltage and resulting current is set at a value to make the gain equal the losses due to the out-coupled light and any parasitic absorption/radiation loss. Thus, coherent light coupled into the LBGSE will travel without change in intensity in the z direction and remain coherent. In this way saturation effects and internal oscillations are avoided. Thus, this invention describes a surface emitting device with an unprecedented-large-coherent-emitting area that results in a light beam with very small divergence due to diffraction.

The lateral emitting width, W_{g}, can be set by adjusting the grating strength and the longitudinal (z) length can be selected to be a fraction or multiple of the lateral width. Thus, for example, if a 1 cm square beam emitting area is chosen the beam divergence in both lateral and longitudinal directions at a wavelength of 1.55 μm will be 1.55×10⁻⁴ radians or ≈8.9×10⁻³ degrees. If the operating wavelength is chosen to be 0.85 μm the divergence will be ≈4.9×10⁻³ degrees. These small divergences would not require the use of any lens for transmission over substantial distances. Appropriate lenses, however, as are know in the art may be used to focus the emitted beams to get extraordinary power density at the focal plane.

The LBGSE can easily be integrated on the same substrate with distributed feedback (DFB) or distributed Bragg reflector (DBR) lasers. An embodiment incorporating such integration is shown in FIGS. 4 and 5. Such a unique master-oscillator power-amplifier (MOPA) arrangement will have the heretofore unavailable capability of providing extremely high optical powers in a narrow coherent beam from a monolithic-integrated chip with minimal use of external optical elements

### BRIEF DESCRIPTION OF THE DRAWINGS

FIG. 1. Perspective schematic drawing of a laterally-symmetric embodiment of a Lateral-Bragg-Grating-Surface-Emitting (LBGSE) Laser/Amplifier.

FIG. 2. Cross section in the x-y plain of the laterally-symmetric embodiment illustrated in FIG. 1.

FIG. 3. Cross section in the x-y plain of the laterally-asymmetric embodiment illustrated in FIG. 1.

FIG. 4. Vector diagram of typical light rays in the Bragg grating wing region.

FIG. 5. Cross-section parallel to the x-z plane through the ridge region of an embodiment of LBGSE which includes a laser (master-oscillator) section

FIG. 6. Plot of the 2^{nd} order Bragg angle Θ_{B}/(°), 1st Order output coupling angle Θ/(°) and the azimuthal angle Φ₀ as a function of the Bragg grating period Λ for an embodiment with an effective wing index nₑ=3.3041. Wavelength=1.55 μm.

FIG. 7. Total second order Bragg reflection for a simple rectangular surface relief grating as grating depth t_{g} is varied at a wavelength of 1.55 μm for grating lengths Wg=0.5 and 0.1 cm. Grating period Λ=0.4764 μm. Θ_{B}=160°. n_{w}=3.5. t_{w}=0.3 μm.

### DETAILED DESCRIPTION

### Transverse Confinement and Gain in the Ridge Region

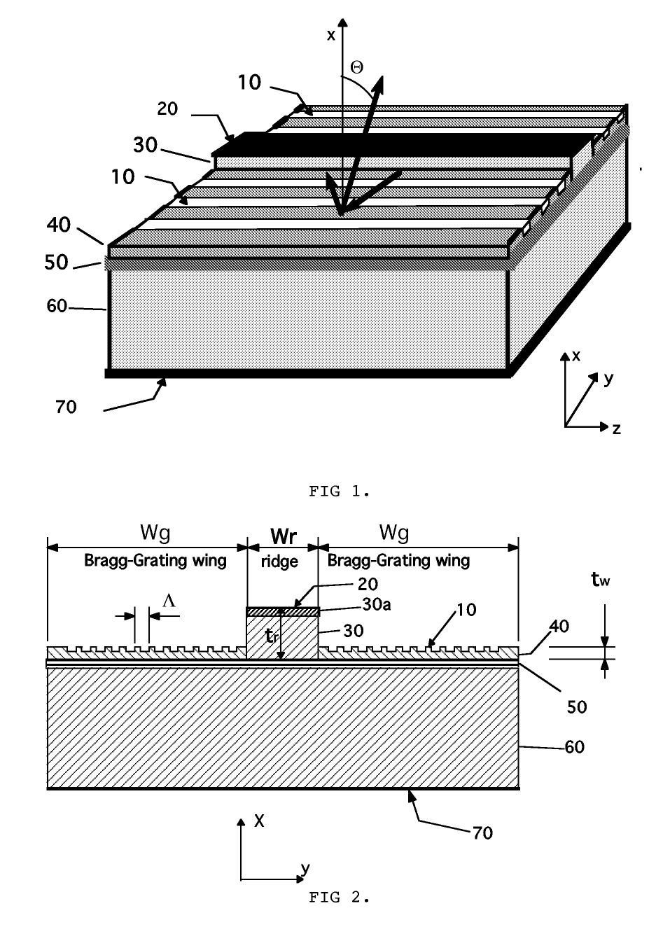

Refer to FIGS. 1,2 and 3. The light is amplified as it travels through the length of the ridge region. Thus, this type of amplifier is called a traveling-wave amplifier.

Refractive index (dielectric) waveguide layers provide optical confinement in the x, or transverse direction. Such waveguides are well known in the field. The ridge has width Wᵣ in the y direction and may have any desired longitudinal length L_{z}.

Under the ridge, a transverse waveguide is formed by substrate 60, amplifier layers 50 and a cover layer 30. The cover layer 30, and the substrate 60 have refractive indexes lower than that of the layers 50, which acts as the transverse guide in the ridge region. The ridge 30 can be of a material similar in refractive index to that of the substrate 60. In the preferred embodiment both ridge and substrate are semiconductor materials that are doped to provide conductivity. For sake of illustration assume the ridge has p-type doping and the substrate n type doping. The ridge would be referred to as the p-clad and the substrate as the n-clad in common semiconductor laser usage. A p+ layer 30a may be used to help make good contact. Contacts 20 on the ridge and 70 on the substrate allow current pumping to provide gain in the ridge region. A guide layer 50 can be an active semiconductor junction.

In the preferred embodiment the layers 50 are semiconductor-multiple-quantum wells and barriers that, as is well known in the field, provide high gain when pumped with current. In the ridge region the refractive indexes are chosen so that a transverse-optical waveguide is ensured.

### Transverse Confinement in the Bragg-Grating Wing Region

The Bragg-grating-wing layer 40 thickness t_{w} and refractive index n_{w} are chosen so that the Bragg-grating-wing layer 40 acts as the transverse-planar-waveguide layer in the wing regions. The width of a Bragg-grating-wing is W_{g}.

To reduce absorption losses the Multi-quantum well layers 50 may be removed in the wing regions and in the preferred embodiment the Bragg-grating-wing layers 40 are not doped to be conductive. In the example calculated below n_{w}=3.5. Also, t_{w} is made large enough (0.3 μm) so that the Bragg-grating-wing layer 40 is the transverse-planar-waveguide layer in the wing region.

### Lateral Confinement (y)

Confinement in the y direction is provided by the lateral Bragg reflecting grating 10 that has period Λ and grating lines that run parallel to the y-axis. The periodic changes that form the Bragg grating occur only in the lateral direction (+y). There is no periodicity in the longitudinal direction (±z) to ensure that there is no resulting feedback to the traveling-wave mode, which flows in the longitudinal direction.

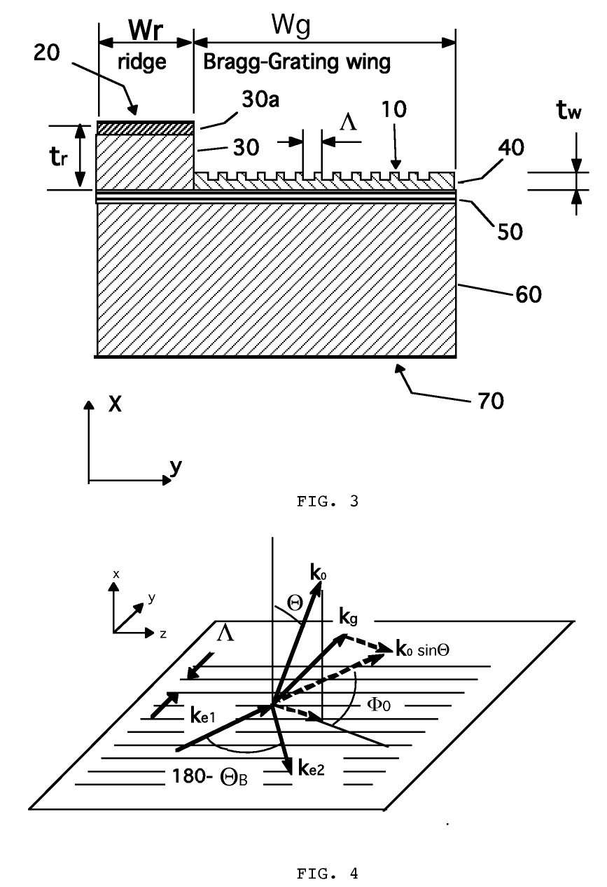

In a preferred embodiment the period is chosen to act so the Bragg grating acts as a light reflector in second order and couples light out of the waveguide plane (out-coupler) in first order. Other orders to achieve this purpose may be used. The Bragg grating may be a surface relief grating as illustrated in FIGS. 2 and 3. Gratings formed by periodic changes in the materials, which result in periodic changes in the refractive may also be used. The periodic changes occur only in the lateral direction.

First-order, Bragg-reflecting-grating confinement in the transverse direction by layers that form a grating have been reported in the literature. [1, 2, 3, 4] Such structures have been called “Transverse Bragg Resonance Waveguides.” There have, however, been no reports of either using Bragg gratings to provide lateral-optical-waveguide confinement to obtain a two dimensional guide or of using Bragg gratings to provide both the lateral confinement and out-coupling as is described in this invention.

The ridge 30 of width Wᵣ does not provide lateral confinement because the refractive index n_{w} and the thickness t_{w} of the wings 40 are chosen so that the effective refractive index of the wing nₑ is higher than the effective refractive index nᵣ of the ridge. In the example calculated below t_{w}=0.3 μm, n_{w}=3.5, nₑ=3.304 and nᵣ=3.21. Under these conditions, in the absence of the lateral Bragg grating, light flowing in the ridge region would be free to radiate in the lateral (±y) direction but is restrained in the transverse (x) direction.

It should also be noted that for minimal loss due to lateral radiation beyond the extent of the grating the width W_{g} would be “quantized in fractions of the” lateral Bragg grating period Λ.[3] In the LBGSE this quantization is less significant because in the preferred embodiment the first order of the Bragg grating will out-couple all the light within the grating width W_{g}.

An asymmetrical embodiment of the LBGSE is illustrated in FIG. 3. In the asymmetrical embodiment the Bragg grating provides lateral confinement on one side of the traveling-wave amplifier (the +y side) of the illustration. The ridge boundary provides lateral confinement on the other side (the −y side) because the ridge will have a higher refractive index than the region on the −y side which may be air or vacuum.

In the preferred embodiment, the period, Λ, of the lateral Bragg reflecting grating 10 is chosen to reflect light in second order through the Bragg angle Θ_{B} measured from the y direction normal to the grating lines. Surface relief gratings are schematically illustrated in FIGS. 2 and 3, but other types of gratings as for instance a grating obtained by a periodic variation in the wing material may also be used.

A Vector diagram of some typical light rays in the Bragg grating wing region is shown in FIG. 4. The lateral-waveguide mode is represented by the incident kₑ₁ and reflected kₑ₂ ray vectors, which are at angle=(180°−Θ_{B})/2 to the grating vector k_{g}. k_{g} is normal to the grating lines. The first grating order operating on kₑ₁ results in out-coupled-ray-vector k₀ at angle Θ to the y axis. A similar output ray, not illustrated in FIG. 4, results from the Bragg reflected ray kₑ₂ in a second plane perpendicular to the grating plane that is rotated through an angle Θ_{B} from the first out put plane. The dashed lines represent projections of the ray vectors. Thus, in the general case there will be two output beams that may be coherent with each other. Both will be at an angle Θ from the y axis but separated by an azimuthal rotation Φ₀=Θ_{B}/2. Suitable external lens and prism arrangements can be used to result in a single output beam as is known in the art.

It should be noted that in addition to the output rays lustrated light will be diffracted towards the substrate which will be called “Downward Rays.” The Downward Rays will have ray angles determined by both the grating period and refraction due to the change in refractive index in passing from surface to substrate. These rays are not illustrated and in general will be absorbed in the substrate.

The Downward Rays may, however, be used if the substrate thickness and/or composition is altered in the wing region and the contact removed. In passing from the substrate to air the emitting angles of the Downward Rays will be identical to the emitting angles of the output rays discussed above.

The Bragg gratings can be blazed to result in a predominant single output beam while minimizing the intensity of the light coupled towards the substrate.

### LBGSE Integrated with a Laser

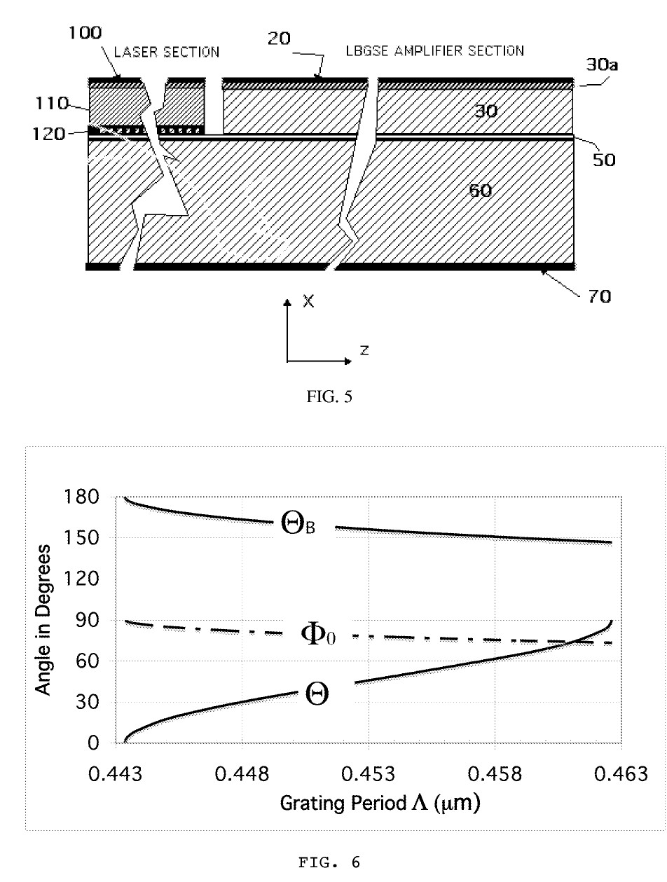

FIG. 5. is a cross-section parallel to the x-z plane through the ridge region of an embodiment of LBGSE which includes a laser section. The laser section is formed on the same substrate as the amplifier section and provided with a contact 100 independent of the amplifier contact 20. The ridge 110 in the laser section has the same width of that in the LBGSE Amplifier Section and may be grown of either the same material, or of a different material, than that of the amplifier ridge 30. A Distributed Feed Back grating (DFB) 120, which reflects light in the z direction is illustrated. An appropriately placed Distributed Bragg Reflector (DBR) grating may be used instead, but is not illustrated. DFB and DBR lasers are well known in the art.

In the preferred embodiment the DFB or DBR gratings operate in first order, and thus, do not couple any light out of the plane of the laser section. FIG. 5 is a cross-section parallel to the x-y plane through the laser section. In the laser section the ridge 110, the wing 120a materials, and geometry is chosen so that the ridge acts as a lateral (y) dielectric waveguide to confine light under the ridge. In this section the lateral Bragg gratings are omitted.

In the laser section, as is well known in the art, current flow results in high gain due to the MQW layer and because of the DFB or DBR gratings efficient-coherent-laser oscillation takes place. In the laser section the current is controlled independently of the current in the amplifier section. The generated light couples into the LBGSE amplifier section through the common transverse guide provided by the active layer 50. A transitional section of waveguide, not illustrated, may be placed between the laser and amplifier to avoid reflection due to effective-lateral-index mismatch.

### Brief Review of Theory

The relations between the angles, refractive indexes and grating period will be summarized in this section. For first order out-coupling and second order Bragg reflection from a grating it may be shown [5] that

n₀ sin Θ=nₑ cos(Θ_{B}/2)

Φ₀=Θ_{B}/2

Λ=λ/[nₑ sin(Θ_{B}/2)]

The angles are illustrated in FIG. 4. Θ_{B} is the second order Bragg reflection angle. Φ₀ is the azimuthal angle through which the output coupled light is rotated from the input direction in the y-z plane and Θ is the output angle measured to the x axis. n₀ is the index of the medium into which the output light is coupled, which for many cases will be air or vacuum with n₀≈1. nₑ is the effective index of the transverse guide in the wing region. λ is the free-space wavelength and Λ is the Lateral Bragg grating period.

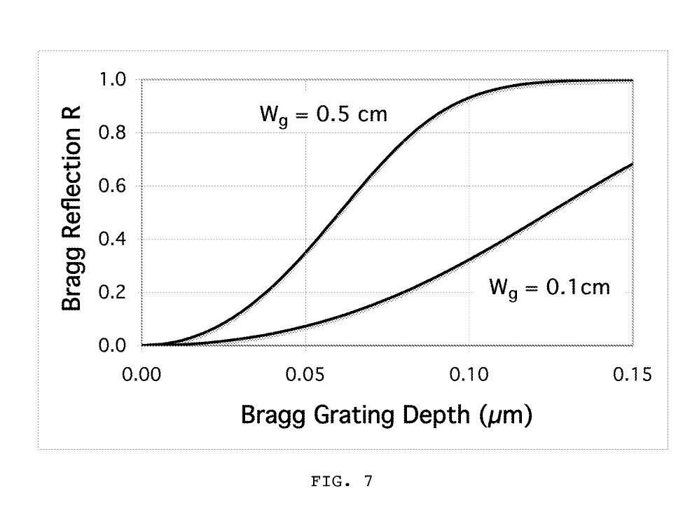

FIG. 6 is a plot of the 2^{nd} order Bragg angle Θ_{B}/(°), the 1st Order output coupling angle Θ/(°) and the azimuthal angle Φ₀/(°) as a function of the Bragg grating period Λ. The wing thickness t_{w}=0.3 μm, and index n_{w}=3.5, which results in an effective wing index nₑ=3.3041. The wavelength λ=1.55 μm. Note that in this example second order Bragg reflection angles less than ≈147.7 degrees would result in output coupling angle Θ greater then 90° and are thus non-physical.

### Estimate of Reflectivity for a Surface-Relief Grating

FIG. 7 shows total estimated second order Bragg reflection R for a simple rectangular surface relief grating as grating depth t_{g} is varied at a wavelength of 1.55 μm for grating lengths W_{g}=0.5 and 0.1 cm. Grating period Λ=0.4764 μm. Θ_{B}=160°. n_{w}=3.5. t_{w}=0.3 μm. As can be seen for a 0.5 cm wide grating (W_{g}=0.5 cm) R≈1.0 (100%) at t_{g}=0.13 μm. At 100% reflection the lateral confinement will be complete and there would be no loss due to lateral leakage but a substantial fraction of the light will be coupled out due to the first order of the lateral Bragg grating. In the optimum embodiment the grating depth and blaze will be chosen so that all the light is coupled out in a lateral distance W_{w} by each grating.

What is claimed is:

1. A device for emitting light consisting of an optical-waveguide amplifier, which will be referred to as “Amplifier.” The Amplifier amplifies light flowing along a length in a given flow direction (z), restrains light from flowing in the first of the two direction perpendicular to the said flow direction (x) and has a width in the second of the two direction perpendicular to the said flow direction (y). The Amplifier is formed on a substrate. The Amplifier is contiguous with two planar waveguides each located on a given side of the Amplifier with plane defined by the said flow direction and the second of the two directions perpendicular to said flow direction (y,z). The said planar waveguides restrains light from flowing in the first of the two directions perpendicular to the said flow direction and are formed on the same substrate as the Amplifier. The planar waveguides contain Bragg diffraction gratings with grating lines parallel to the given flow direction. A particular grating order of said Bragg diffraction gratings causes light to be emitted out of the waveguide plane at angle less than 90° to the said first of the two directions perpendicular to the said flow direction. Another grating order of said diffraction grating reflects light at angle less than 90° to the second of the said two directions perpendicular to said flow direction.

2. The device of claim 1 in which the Amplifier and the substrate are semiconductors.

3. The device of claim 1 in which the waveguides containing diffraction gratings are semiconductors without conductive dopants

4. The device of claim 1 in which the first order of said Bragg diffraction gratings causes light to be emitted out of the waveguide at angle less than 90° to the said first of the two directions perpendicular to the said flow direction. The second order of said Bragg diffraction gratings reflects light at angle less than 90° to the second of the said two directions perpendicular to said flow direction.

5. The device of claim 4 in which the Amplifier and the substrate are semiconductors.

6. The device of claim 4 in which the waveguides containing diffraction gratings are semiconductors without conductive dopants.

7. A device for emitting light consisting of an Amplifier. The Amplifier amplifies light flowing along a length in a given flow direction (z), restrains light from flowing in the first of the two direction perpendicular to the said flow direction (x) and has a width in the second of the two direction perpendicular to the said flow direction (y). The Amplifier is formed on a substrate. The said Amplifier is contiguous to a planar waveguides located on a given side of the Amplifier with plane defined by the said flow direction and the second of the two directions perpendicular to said flow direction (y,z). The said planar waveguide restrains light from flowing in the first of the two directions perpendicular to the said flow direction and is formed on the same substrate as the Amplifier. The planar waveguide contains a Bragg diffraction gratings with grating lines parallel to the given flow direction. A particular grating order of said diffraction grating causes light to be emitted out of the waveguide plane at angles less than 90° to the said first of the two directions perpendicular to the said flow direction. Another grating order of said diffraction grating reflects light at angle less than 90° to the second of the said two directions perpendicular to said flow direction.

8. The device of claim 7 in which the Amplifier and the substrate are semiconductors.

9. The device of claim 7 in which the waveguides containing diffraction gratings are semiconductors without conductive dopants

10. The device of claim 7 in which the first order of said Bragg diffraction grating causes light to be emitted out of the waveguide at angle less than 90° to the said first of the two directions perpendicular to the said flow direction. The second order of said Bragg diffraction grating reflects light at angle less than 90° to the second of the said two directions perpendicular to said flow direction.

11. The device of claim 10 in which the Amplifier and the substrate are semiconductors.

12. The device of claim 10 in which the waveguides containing diffraction gratings are semiconductors without conductive dopants.

13. A system consisting of a Distributed Feedback (DFB) laser formed on the same substrate as the optical amplifier of claim 2 and positioned so that the laser light flows in the said given flow direction and into the Amplifier.

14. A system consisting of a Distributed Bragg Reflector (DBR) laser formed on the same substrate as the optical amplifier of claim 2 and positioned so that the laser light flows in the said given flow direction and into the Amplifier.

15. A system consisting of a Distributed Feedback (DFB) laser formed on the same substrate as the Amplifier of claim 5 and positioned so that the laser light flows in the said given flow direction and into the Amplifier.

16. A system consisting of a Distributed Bragg Reflector (DBR) laser formed on the same substrate as the Amplifier of claim 5 and positioned so that the laser light flows in the said given flow direction and into the Amplifier.

17. A system consisting of a Distributed Feedback (DFB) laser formed on the same substrate as the Amplifier of claim 8 and positioned so that the laser light flows in the said given flow direction and into the Amplifier.

18. A system consisting of a Distributed Bragg Reflector (DBR) laser formed on the same substrate as the optical amplifier of claim 8 and positioned so that the laser light flows in the said given flow direction and into Amplifier.

19. A system consisting of a Distributed Feedback (DFB) laser formed on the same substrate as the Amplifier of claim 11 and positioned so that the laser light flows in the said given flow direction and into the Amplifier.

20. A system consisting of a Distributed Bragg Reflector (DBR) laser formed on the same substrate as the Amplifier of claim 11 and positioned so that the laser light flows in the said given flow direction and into the optical a Amplifier.
